(19) United States
(12) Patent Application Publication
(10) Pub. No.: US 2005/0272244 A1
(43) Pub. Date: Dec. 8, 2005

(54) Method for manufacturing circuit element, method for manufacturing electronic element, circuit substrate, electronic device, and electro-optical apparatus

(75) Inventor: Kenji Wada, Fujimi-machi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/113,097

(22) Filed: Apr. 25, 2005

(30) Foreign Application Priority Data
Jun. 8, 2004 (JP) 2004-170101

(51) Int. Cl. H01L 21/20; H01L 21/44

(52) U.S. Cl. 438/614; 438/613; 438/612; 438/584; 438/674

(57) ABSTRACT

The present invention aims to provide a mounting technology that prevents unnecessary consumption of materials. A method for manufacturing a circuit element includes the steps of: setting a semiconductor element on a stage so that a metal pad of the semiconductor element faces a head; changing positions of the head relative to the semiconductor element; dispensing a liquid conductive material from a nozzle so that the conductive material is coated on the metal pad when the nozzle reaches a position corresponding to the metal pad; and either activating or drying the coated conductive material in order to obtain a UBM layer on the metal pad.

### BACKGROUND

The present invention relates to a method for manufacturing a circuit element, a method for manufacturing an electronic element, a circuit substrate, an electronic device, and an electro-optical apparatus.

Flip chip bonding is used as a technique to bond semiconductor elements such as LSI in a small mounting area. Further, for more stable flip chip bonding, an under bump metallurgy (UBM) layer is provided between a semiconductor element and a metal pad. In contract, a metal coating technique using an ink-jet method is also known (for example, in Patent Document 1).

[Patent Document 1] Japanese Unexamined Patent Publication No. 2004-6578.

### SUMMARY

The UBM layer is formed by sputtering or plating. However, both methods of sputtering and plating include a step of depositing a metal material on an almost entire surface of the semiconductor element and a step of removing the metal material from an area where the UBM layer is not needed. Therefore, such conventional UBM layer formation method involves unnecessary consumption of metal material.

On the contrary, it is not known to form the UBM layer using the ink-jet method.

In view of the above-mentioned issues, one of the objectives of the present invention is to provide a mounting technique to prevent extra consumption of the material.

The method for manufacturing a circuit element of the present invention is the method utilizing a dispenser which is provided with a stage and a head having a nozzle that faces the stage. This manufacturing method includes: the step A of setting a semiconductor element on the stage so that a metal pad of the semiconductor element faces the head; the step B of changing positions of the head relative to the semiconductor element; the step C of dispensing a liquid conductive material from the nozzle so that the conductive material is supplied onto the metal pad when the nozzle reaches a position corresponding to the metal pad; and the step D of either activating or drying the supplied conductive material in order to obtain a UBM layer on the metal pad.

One of the effects exerted by the above-described configuration is low consumption of the conductive material required to form the UBM layer. This is because the conductive material can be selectively supplied onto the metal pad.

According to an aspect of the present invention, the step C includes the step of dispensing a first liquid conductive material from a first nozzle so that the first conductive material is supplied onto the metal pad, and the step D includes the step of either activating or drying the supplied first conductive material in order to obtain a first metal layer on the metal pad.

One of the effects exerted by the above-described configuration is low consumption of the first conductive material required to form the UBM layer. This is because the first conductive material can be selectively supplied onto the metal pad.

According to another aspect of the present invention, the step C further includes the step of dispensing a second liquid conductive material from a second nozzle so that the second conductive material is supplied onto the first metal layer, and the step D further includes the step of either activating or drying the supplied second conductive material in order to obtain a second metal layer on the first metal layer.

One of the effects exerted by the above-described configuration is that the UBM layer having two metal layers can be obtained.

According to yet another aspect of the present invention, the step C further includes the step of dispensing a third liquid conductive material from a third nozzle so that the third conductive material is supplied onto the second metal layer, and the step D further includes the step of either activating or drying the supplied third conductive material in order to obtain a third metal layer on the second metal layer.

One of the effects exerted by the above-described configuration is that the UBM layer having three metal layers can be obtained.

Preferably, the first conductive material contains fine particles of titanium; the second conductive material contains fine particles of nickel; and the third conductive material contains fine particles of gold.

One of the effects exerted by the above-described configuration is that the UBM layer that can realize a stable solder bump can be obtained.

According to a further aspect of the present invention, the method for manufacturing the above-referenced circuit substrate further includes the step E of forming a solder bump on the UBM layer and the step F of reflowing the solder bump.

One of the effects exerted by the above-referenced configuration is that the solder bump that can realize stable flip chip bonding can be obtained.

According to an aspect of the present invention, the circuit substrate is manufactured by the above-referenced method for manufacturing the circuit element. According to another aspect of the present invention, an electronic device is manufactured by the above-referenced method for manufacturing the circuit element. According to a further aspect of the present invention, an electro-optical apparatus is manufactured by the above-referenced method for manufacturing the circuit element.

The method for manufacturing an electronic element of the present invention is the method utilizing a dispenser which is provided with a stage and a head having a nozzle that faces the stage. This manufacturing method includes: the step A of setting a substrate on the stage so that a conductive terminal of the substrate faces the head; the step B of changing positions of the head relative to the substrate; the step C of dispensing a liquid conductive material from the nozzle so that the conductive material is supplied onto the conductive terminal when the nozzle reaches a position corresponding to the conductive terminal; and the step D of either activating or drying the supplied conductive material in order to obtain a UBM layer on the conductive terminal.

One of the effects exerted by the above-referenced configuration is low consumption of the conductive material required to form the UBM layer. This is because the conductive material can be selectively supplied onto the conductive terminal.

### BRIEF DESCRIPTION OF THE DRAWINGS

FIG. 1A is a pattern diagram showing a plan view of a semiconductor chip, and FIG. 1B is a pattern diagram of a semiconductor wafer;

FIG. 2 is a pattern diagram of a manufacturing apparatus of the present embodiment;

FIG. 3 is a pattern diagram of a dispenser;

FIGS. 4A and 4B are diagrams of a head of the dispenser;

FIGS. 5A to 5C are diagrams illustrating a method for providing a UBM layer;

FIGS. 6A to 6C are diagrams illustrating the method for providing the UBM layer;

FIGS. 7A and 7B are diagrams illustrating the method for providing the UBM layer;

FIGS. 8A to 8D are diagrams illustrating a method for forming solder bumps;

FIGS. 9A and 8B are diagrams illustrating a method for mounting the semiconductor chip on a wiring substrate;

FIG. 10 is a pattern diagram of a liquid-crystal display device manufactured by the manufacturing method of the present embodiment;

FIG. 11 is a pattern diagram of the liquid-crystal display device manufactured by the manufacturing method of the present embodiment;

FIG. 12 is a pattern diagram of a cellular phone manufactured by the manufacturing method of the present embodiment; and

FIG. 13 is a pattern diagram of a personal computer manufactured by the manufacturing method of the present embodiment.

### DETAILED DESCRIPTION OF EMBODIMENTS

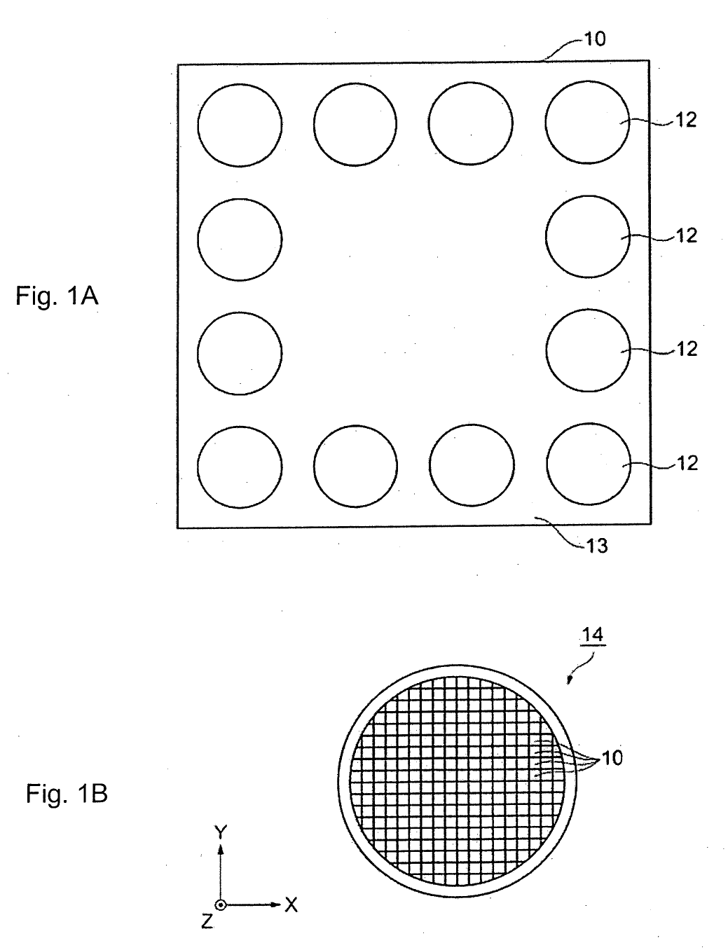

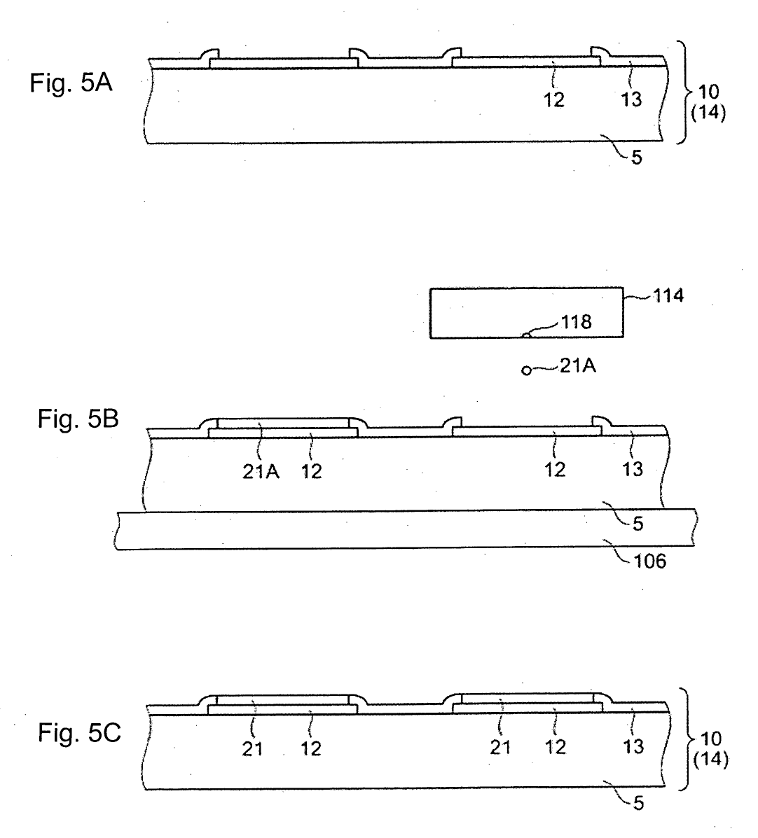

A semiconductor chip 10 of FIG. 1A is a semiconductor element to be mounted on a wiring substrate or on other semiconductor chips by the flip chip technology. More specifically, an integrated circuit not shown in the drawings is formed on the semiconductor chip 10. Further, the semiconductor chip 10 includes a plurality of metal pads 12 electrically coupled with the integrated circuit. These integrated circuits and metal pads 12 are provided on the side of a base substrate 5 (FIG. 5) of the semiconductor chip 10.

Further, the shape of the semiconductor chip 10 of FIG. 1A is almost square. Also, the semiconductor chip 10 includes twelve metal pads 12 lined along the periphery of the semiconductor chip 10. Furthermore, the surface of the semiconductor chip 10 is coated with an insulating layer 13. Note that the insulating layer 13 is patterned in such a way that only the surfaces of the metal pads 12 are exposed.

On each of the plurality of metal pads 12, the under bump metallurgy (UBM) layer is to be provided using a manufacturing apparatus which will be described later. Then, on the provided UBM layer, a solder bump is to be provided by a method such as plating, ball mounting, dipping, or printing. In the present specification, the semiconductor chip 10 with the solder bumps provided thereon is also expressed as “circuit element.”

The semiconductor chip 10 with the solder bumps provided thereon will be mounted on the wiring substrate. More specifically, the semiconductor chip 10 is positioned against the wiring substrate so that each provided solder bump comes in contact with its corresponding land provided on the wiring substrate, which will be described later. Then, by melting the solder bump, the semiconductor chip 10 is physically and electrically connected with the wiring substrate. In other words, the semiconductor chip 10 is mounted on the wiring substrate. In the present specification, the wiring substrate with the semiconductor chip 10 mounted thereon is also expressed as “circuit substrate.”

The metal constituting the metal pad 12 is mainly aluminum. Generally speaking, wettability of solder to such metal pad 12 is not good. Therefore, it is physically difficult to connect the solder bump to the metal pad 12. For this reason, it is desirable to provide a conductive layer having good affinity for the solder bump on the metal pad 12. In the present embodiment, the UBM layer is such conductive layer.

In the present embodiment, the surface of the metal pad 12 may be expressed as “landing part” or “target.” “Landing part” or “target” means a part at which the liquid material dispensed from the dispenser (to be described later) lands and spreads. Further, a thin film may be formed on the surface of the metal pad 12 in such a manner that the liquid conductive material landed on the metal pad 12 has a desired contact angle. In the present embodiment, such a thin film formed on the surface of the metal pad 12 is altogether expressed as “metal pad.”

In the present embodiment, the semiconductor chips 10 are manufactured taking a configuration of a semiconductor wafer 14 as shown in FIG. 1B. In the present embodiment, the processes for providing the solder bumps on the UBM layers are carried out with the plurality of semiconductor chips 10 of the semiconductor wafer 14. These processes for providing the solder bumps may naturally be conducted with separate semiconductor chips 10 which were cut up by dicing the semiconductor wafer 14.

In the following, the manufacturing apparatus that provides the UBM layer on each of the plurality of metal pads 12 of the semiconductor chip 10 will be described. Additionally, the manufacturing apparatus as will be described below is a part of manufacturing instrument that manufactures the circuit substrate.

(A. Manufacturing Apparatus)

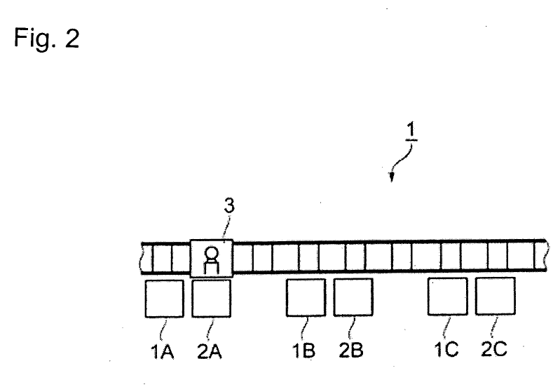

A manufacturing apparatus 1 of FIG. 2 includes three dispensers 1A, 1B, and 1C, three ovens (dryers) 2A, 2B, and 2C, and a transporter 3.

The dispenser 1A is a device for coating or supplying the first conductive material on the metal pad 12 of the semiconductor chip 10. Here, the first conductive material contains nanoparticles of titanium (Ti), a dispersing agent to coat the surface of the titanium nanoparticles, and an organic solvent. The oven 2A is a device to heat the coated first conductive material. Heated by the oven 2A, titanium contained in the first conductive material is sintered, and, thereby the first metal layer is obtained.

The dispenser 1B is a device for coating or supplying the second conductive material on the first metal layer. Here, the second conductive material contains nanoparticles of nickel (Ni), a dispersing agent to coat the surface of the nickel nanoparticles, and an organic solvent. The oven 2B is a device to heat the coated second conductive material. Heated by the oven 2B, nickel contained in the second conductive material is sintered, and, thereby the second metal layer is obtained.

The dispenser 1C is a device for coating or supplying the third conductive material on the second metal layer. Here, the third conductive material contains nanoparticles of gold (Au), a dispersing agent to coat the surface of the gold nanoparticles, and an organic solvent. The oven 2C is a device to heat the coated third conductive material. Heated by the oven 2C, gold contained in the third conductive material is sintered, and, thereby the third metal layer is obtained.

The transporter 3 is equipped with a self-propelling unit and a lift with two forks to support the semiconductor wafer 14. In addition, the transporter 3 supplies the semiconductor chips 10 (semiconductor wafer 14) to, and in the order of, the dispenser 1A, the oven 2A, the dispenser 1B, the oven 2B, the dispenser 1C, and the oven 2C.

In the following, the dispensers 1A, 1B, and 1C will be described of their compositions and functions in more detail. It should be noted that the dispensers 1B and 1C have basically the same compositions and functions as those of the dispenser 1A. Thus, to avoid repetition, the dispenser 1A will be described representing the other two. Further, in the present specification, the numbers referencing the composition elements of the dispenser 1A are given to the like composition elements of the dispensers 1B and 1C.

(B. Dispenser)

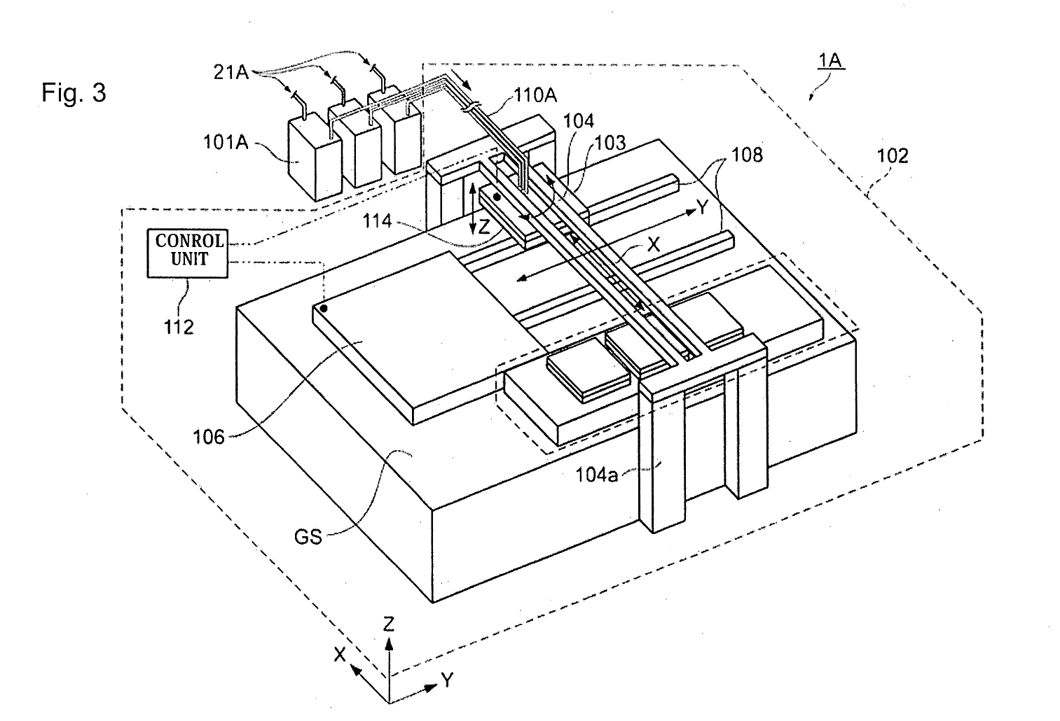

The dispenser 1A shown in FIG. 3 is an ink-jet device. More specifically, the dispenser 1A is equipped with a tank 101A to hold a first liquid conductive material 21A, a tube 110A, and a dispenser scan unit 102 to receive the liquid conductive material 21A from the tank 101A through the tube 110A. Here, the dispenser scan unit 102 is equipped with a grand stage GS, a dispenser head part 103, a stage 106, a first position controller 104, a second position controller 108, a controlling part 112, and a supporting part 104a.

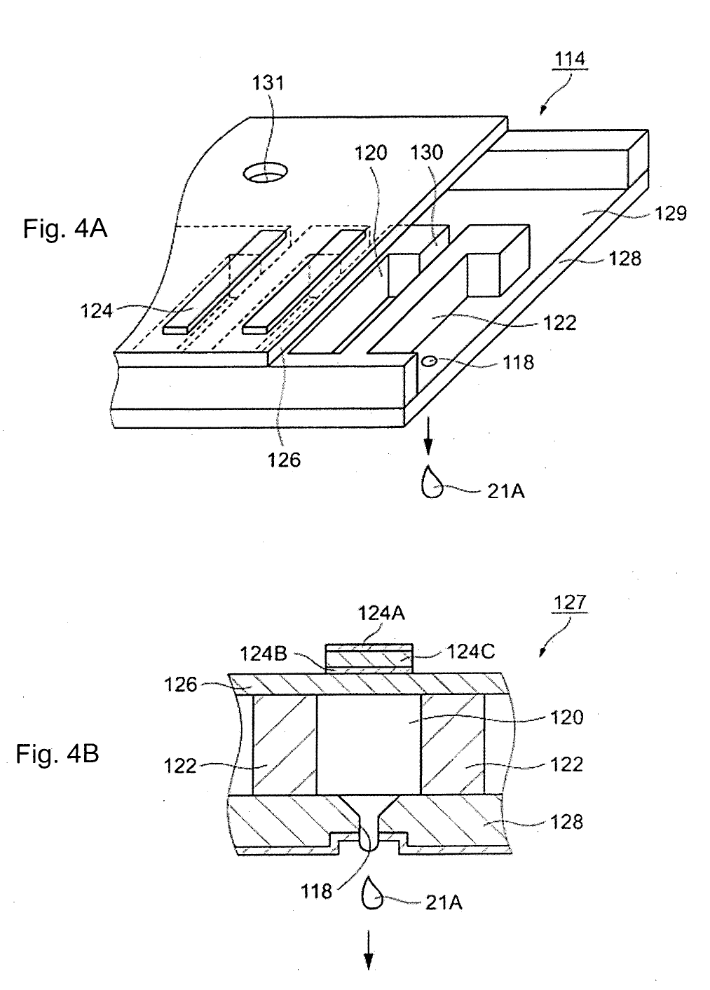

The dispenser head part 103 holds a head 114 (FIG. 4) that dispenses the first liquid conductive material 21A at the side of the stage 106. This head 114 dispenses droplets of the first liquid conductive material 21A in response to a signal coming from the controlling part 112. Further, the head 114 of the dispenser head part 103 is linked with the tank 101A by the tube 110A, and, thereby, the first liquid conductive material 21A is supplied from the tank 101A to the head 114.

Note that the first liquid conductive material 21A is a kind of “liquid material.” “Liquid material” is a material having viscosity that can be dispensed as droplets from a nozzle (to be described later) of the head 114. In this case, it does not matter whether the material is aqueous or oily liquid. The material only needs to have enough flowability (viscosity) to get dispensed from the nozzle, and it may include solid substances if it takes, as a whole, a form of fluid. In the present embodiment, the first liquid conductive material 21A contains titanium particles having an average particle diameter of around 10 nm, a dispersing agent, and an organic solvent. In the first liquid conductive material 21A, the titanium particles are coated with the dispersing agent. The titanium particles coated with the dispersing agent is stably dispersed in the organic solvent. Here, the dispersing agent is a compound that can be coordinated to titanium atom.

As the dispersing agent, amine, alcohol, and thiol are known. More specifically, as the dispersing agent, an amine compound such as 2-methylaminoethanol, diethanolamine, diethylmethylamine, 2-dimethylaminoethanol, or methyldiethanolamine, alkylamines, ethylendiamine, alkylalchols, ethyleneglycol, propyleneglycol, alkylethiols, or ethanedithiol can be used.

Further, a particle having an average diameter of one nanometer to some hundred nanometers is also expressed as “nanoparticle.” According to this expression, the first liquid conductive material 21A includes titanium nanoparticles.

The stage 106 has a flat surface on which the semiconductor wafer 14 is mounted. Further, the stage 16 also has a function to fix the position of the semiconductor wafer 14 by vacuuming.

The first position controller 104 is fixed at a position having a given height from the ground stage GS by the supporting part 104a. This first position controller 104 has a function to move the dispenser head part 103 along an X-axis direction as well as along a Z-axis direction perpendicular to the X-axis direction in response to a signal from the controlling part 112. Further, the first position controller 104 also has a function to rotate the dispenser head part 103 around an axis paralleling the Z-axis. Here, in the present embodiment, the Z-axis direction is a direction parallel to a vertical direction, that is, to a gravitational acceleration direction.

The second position controller 108 moves the stage 106 in a Y-axis direction on the grand stage GS in response to a signal from the controlling part 112. Here, the Y-axis direction is the direction perpendicular to both the X-axis and Z-axis directions.

Because the first and second position controllers 104 and 108 having the aforementioned functions can be composed by use of a well-known XY robot utilizing a linear motor and a servomotor, detailed descriptions of their compositions are omitted here.

The dispenser head part 103 moves in the X-axis direction by the first position controller 104. Then, the semiconductor wafer 14, together with the stage 106, moves in the Y-axis direction by the second position controller 108. Consequently, the position of the head 114 relative to the semiconductor chips 10 (semiconductor wafer 14) shifts. More specifically, by these operations, the dispenser head part 103, the head 114, or the nozzle 118 (FIG. 4) moves, that is to say, scans in the X-axis and Y-axis directions relative to the semiconductor chips 10 while keeping certain distance in the Z-axis direction. “Move relative to . . . ” or “scan relative to . . . ” means that at least one side moves relative to the other side, one side being the side to dispense the first liquid conductive material 21A and the other side (the landing part) being the side to receive the dispensed material.

The controlling part 112 is composed is such a way that it receives dispensation data (e.g., bit map data), which shows relative positions of the droplets of the first liquid conductive material 21A to be dispensed, from an outside data processing system. The controlling part 112 stores the received dispensation data in the inside memory system as well as controls the first position controller 104, the second position controller 108, and the head 114 in accordance with the stored dispensation data.

(C. Head)

As shown in FIG. 4A and FIG. 4B, the head 114 of the dispenser 1A is an ink-jet head. More specifically, the head 114 is equipped with an oscillating board 126 and a nozzle plate 128. Between the oscillating board 126 and the nozzle plate 128 is located a liquid reservoir 129, into which the first liquid conductive material 21A supplied via a through hole 131 from an outside tank (not shown) is filled constantly.

Also, between the oscillating board 126 and the nozzle plate 128 are located a plurality of dividing fences 122. Further, surrounded by the oscillating board, the nozzle plate 128, and a pair of the dividing fences 122 is a cavity 120. Because the cavity 120 is provided corresponding to the nozzle 118, the number of the cavities 120 is equal to the number of the nozzles 118. Into the cavities 120, the first liquid conductive material 21A is supplied from the liquid reservoir 129 via a supply mouth 130 placed between the pair of dividing fences 122. In addition, in the present embodiment, the diameter of the nozzle 118 is about 27 μm.

Here, the nozzle 118 of the head 114 of the dispenser 1A corresponds to the “first nozzle” of the present invention. Similarly, the nozzle 118 of the head 114 of the dispenser 1B corresponds to the “second nozzle” of the present invention, and the nozzle 118 of the head 114 of the dispenser 1C corresponds to the “third nozzle.”

Additionally, as will be described later, the “first nozzle,” “second nozzle,” and “third nozzle” may be three different nozzles 118 of one dispenser. Alternatively, the “first nozzle,” “second nozzle,” and “third nozzle” may be three identical nozzles 118 of one dispenser.

Now, on the oscillating board 126, each oscillator 124 is located corresponding to each cavity 120. Each oscillator 124 contains a piezo element 124C and a pair of electrodes 124A and 124B interposing the piezo element 124C. When the controlling part 112 provides driving voltage between this pair of electrodes 124A and 124B, the first liquid conductive material 21A is dispensed from the corresponding nozzle 118. Here, the volume of the first liquid conductive material 21A dispensed from the nozzle 118 can be changed from 0 pl (pico liter) or more to 42 pl or less. Further, the shape of the nozzle 118 is adjusted so that the first liquid conductive material 21A is dispensed from the nozzle 118 in the Z-axis direction.

In the present specification, a section that includes one nozzle 118, one cavity 120 corresponding to the nozzle 118, and the oscillator 124 corresponding to the cavity 120 may sometimes be expressed as a “dispensing section 127.” By this expression, one head 114 is to include the same number of dispensing sections 127 as that of the nozzles 118. The dispensing section 127 may include an electro-thermal converter as a substitute for the piezo element. In other words, the dispensing section 127 may have a composition that dispenses the material by use of thermal expansion of the material by the electro-thermal converter.

(D. Manufacturing Method)

In the following, the method for manufacturing the circuit element is described. This manufacturing method includes the steps of: providing the UBM layer on each of the plurality of metal pads 12 of the semiconductor chip 10; providing the solder bump on the UBM layer; and mounting the semiconductor chip 10 on the wiring substrate.

(D1. Process for Forming Metal Pad)

First, by use of the well-known coating technique and patterning technique, the plurality of metal pads 12 shown in FIG. 5A are provided on each of the plurality of semiconductor chips 10 of the semiconductor wafer 14. In the present embodiment, each of the plurality of metal pads 12 is made of aluminum having a thickness of about 0.5 μm. Further, each metal pad 12 is electrically coupled with an integrated circuit of the semiconductor chip 10. Additionally, in FIG. 5A, the metal pad 12 is formed on the base substrate 5 which is the lowest layer of the semiconductor chip 10.

Next, an insulating material is coated to cover the metal pad 12 and the surface of the semiconductor chip 10. Then, the insulating layer 13 (FIG. 5A) is obtained by patterning the insulating material in a manner that only the metal pad 12 is exposed. In the present embodiment, the obtained insulating layer 13 is a SiO₂ film having a thickness of about 1 μm. Naturally, as the insulating layer 13, a SiN film, a Si₃N₄ film, a polyimide resin film, or the like may be used.

(D2. Process for Forming UBM Layer)

Patterning of the insulating layer 13 is followed by the step of providing the UBM layer on the metal pad 12. This step includes a coating process and a heating process. In the present embodiment, the coating process and the heating process are repeated.

At first, and more specifically, the transporter 3 sets the semiconductor chips 10 (semiconductor wafer 14) onto the stage 106 of the dispenser 1A so that the metal pad 12 of the semiconductor chip 10 faces the head 114. Then, the dispenser 1A changes positions of the nozzle 118 relative to the semiconductor chip 10. Then, as shown in FIG. 5B, when the nozzle 118 reaches the position corresponding to the metal pad 12, the dispenser 1A dispenses the first liquid conductive material 21A from the nozzle 118. Hence, the dispenser 1A coats, that is, supplies the first liquid conductive material 21A only on the metal pad 12.

After coating the first conductive material 21A on all the metal pads 12, the first conductive material 21A is activated. For this purpose, the transporter 3 places the semiconductor chip 10 inside the oven 2A. Then, when the oven 2A heats the semiconductor chip 10 for only a given period of time, the titanium nanoparticles of the first conductive material 21A are either welded or sintered. When the titanium nanoparticles are welded or sintered, the first metal layer 21 covering the metal pad 12 is obtained as shown in FIG. 5C. The first metal layer 21 (Ti layer) obtained in the present embodiment has a thickness of about 0.1 μm.

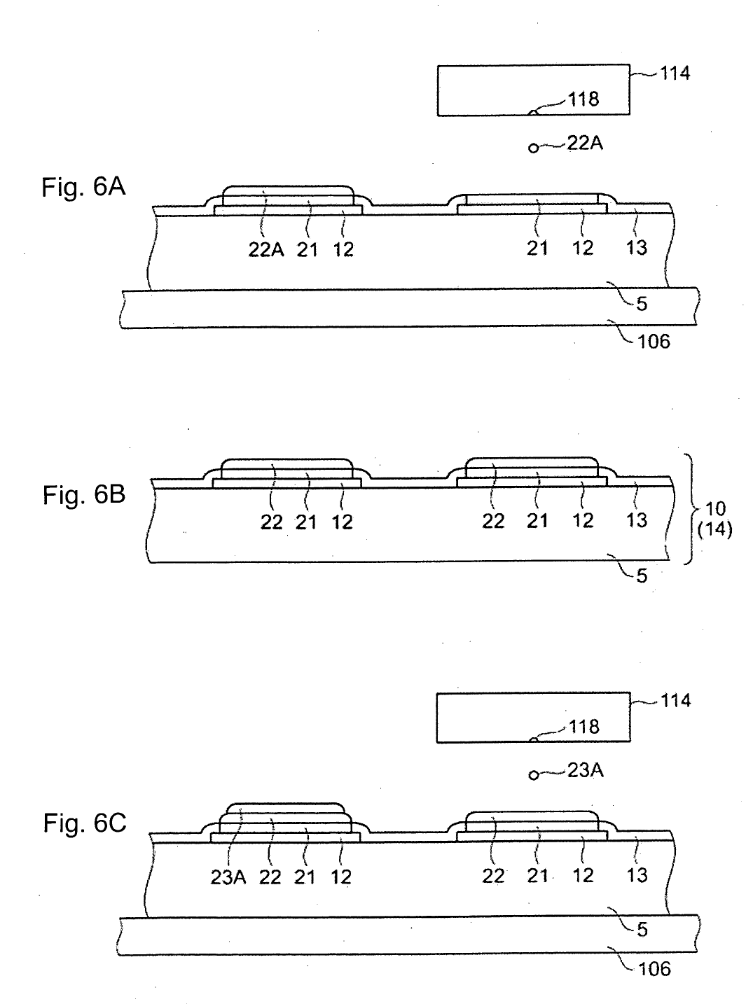

Upon obtaining the first metal layer 21, the transporter 3 sets the semiconductor chip 10 onto the stage 106 of the dispenser 1B so that the metal layer 21 faces the side of the head 114. Consequently, the dispenser 1B changes positions of the nozzle 118 corresponding to the semiconductor chip 10. Then, as shown in FIG. 6A, when the nozzle 118 reaches the position corresponding to the metal pad 12, the dispenser 1B dispenses the second liquid conductive material 22A from the nozzle 118. Hence, the dispenser 1B coats, that is, supplies the second conductive material 22A only on the first metal layer 21.

After coating the second conductive material 22A on all the first metal layers 21, the second conductive material 22A is activated. For this purpose, the transporter 3 places the semiconductor chip 10 inside the oven 2B. Then, when the oven 2B heats the semiconductor chip 10 for a given period of time, the nickel nanoparticles of the second conductive material 22A are either welded or sintered. When the nickel nanoparticles are welded or sintered, the second metal layer 22 covering the first metal layer 21 is obtained as shown in FIG. 6B. The second metal layer 22 (Ni layer) obtained in the present embodiment has a thickness of about 6 μm.

Upon obtaining the second metal layer 22, the transporter 3 sets the semiconductor chip 10 onto the stage 106 of the dispenser 1C so that the second metal layer 22 faces the head 114. Consequently, the dispenser 1C changes positions of the nozzle 118 relative to the semiconductor chip 10. Then, as shown in FIG. 6C, when the nozzle 118 reaches the position corresponding to the metal pad 12, the dispenser 1C dispenses the third liquid conductive material 23A from the nozzle 118. Hence, the dispenser 1C coats, that is, supplies the third conductive material 23A only on the second metal layer 22.

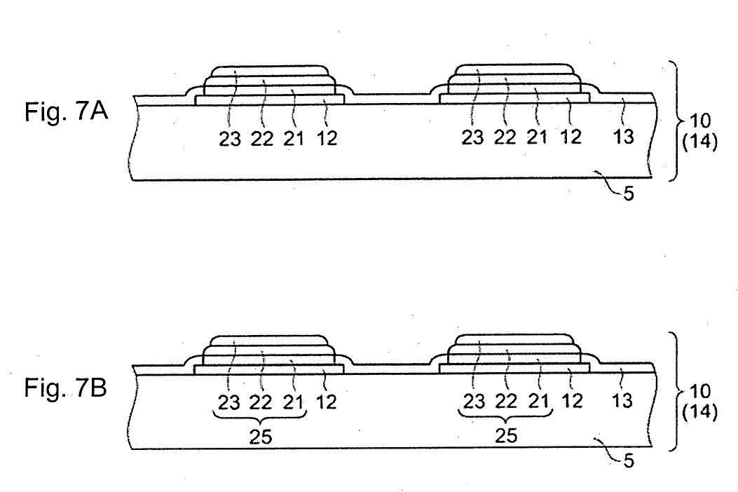

After coating the third conductive material 23A on all the second metal layers 22, the third conductive material 23A is activated. For this purpose, the transporter 3 places the semiconductor chip 10 inside the oven 2C. Then, when the oven 2C heats the semiconductor chip 10 for a given period of time, the gold nanoparticles of the third conductive material 23A are either welded or sintered. When the gold nanoparticles are welded or sintered, the third metal layer 23 covering the second metal layer 22 is obtained as shown in FIG. 7A. The third metal layer 23 (Au layer) obtained in the present embodiment has a thickness of about 10 μm.

By repeating the aforementioned coating and heating processes, a UBM layer 25 is obtained on each of the plurality of metal pads 12 as shown in FIG. 7B. Here, the UBM layer 25 is composed of the first metal layer 21 (titan layer), second metal layer 22 (nickel layer), and third metal layer 23 (gold layer).

As shown, by the present embodiment, the dispensers 1A, 1B, and 1C selectively coat the conductive materials 21A, 22A, and 23A, respectively, only on the desired area. Therefore, unnecessary consumption of the conductive materials in the manufacture of the UBM layer 25 can be prevented.

Now, because the first metal layer 21 is made of titanium, the first metal layer 21 acts as a diffusion barrier layer when a solder layer, which will be described later, is reflowed. Further, because the first metal layer 21 is made of titanium, it adheres well to the metal pad 12 made of aluminum. Other than titanium, metals that adhere well to aluminum are chromium (Cr), titan/tungsten (Ti/W), and nickel (Ni). Therefore, the first metal layer 21 may be made of chromium (Cr), titan/tungsten (Ti/W), or nickel. In this case, in order to obtain the first metal layer 21 made of chromium, titan/tungsten, or nickel, a liquid conductive material containing corresponding fine metal particles needs to be dispensed as a substitute for the titanium fine particles. Additionally, the thickness of the first metal layer 21 can be somewhere between 0.01 μm and 1 μm.

Since the second metal layer 22 is made of nickel, it has good solderability to the solder bump which will be described later. Other than nickel, another metal having good solderability is copper. Therefore, the second metal layer 22 may be made of copper. In this case, in order to obtain the second metal layer 22 made of copper, a liquid conductive material containing corresponding fine copper particles needs to be dispensed as a substitute for the nickel particles. Additionally, the thickness of the second metal layer 22 can be somewhere between 1 μm and 10 μm.

The third metal layer (Au layer) 23 acts as a protection against oxidation of the underlying first metal layer 21, second metal layer 22, and third metal layer 23. Further, the third metal layer 23 made of gold has a function to improve wettability of the solder. Furthermore, because the third metal layer 23 is made of gold, instead of soldering, the third metal layer 23 can be applied to coupling that employs Au—Sn bonding, Au—Au bonding by a wire bonding technique, bonding using anisotropic conductive film (ACF), bonding using anisotropic conductive paste (ACP), bonding using non-conductive film (NCF), or bonding using non-conductive paste (NCP).

Additionally, when the third metal layer 23 is made of gold, it can have a thickness of up to about 20 μm, giving more freedom in designing the height of the UBM layer. As a result, the degree of freedom increases when mounting the circuit element having the UBM layer onto the wiring substrate. Further, the third metal layer 23 of the present embodiment disappears when reflowing the solder layer to form the solder bump. The reason that the third metal layer 23 disappears is that the Au atoms of the third metal layer 23 diffuse while reflowing.

Additionally, in the present embodiment, the multiple layers stacked together such as the first, second, and third metal layers 21, 22, and 23 are altogether expressed also as a “stacked metal layer.”

(D3. Process for Forming Solder Bump)

After providing the UBM layer 25 on the metal pad 12, the process for providing the solder bumps on the UBM layer is carried out.

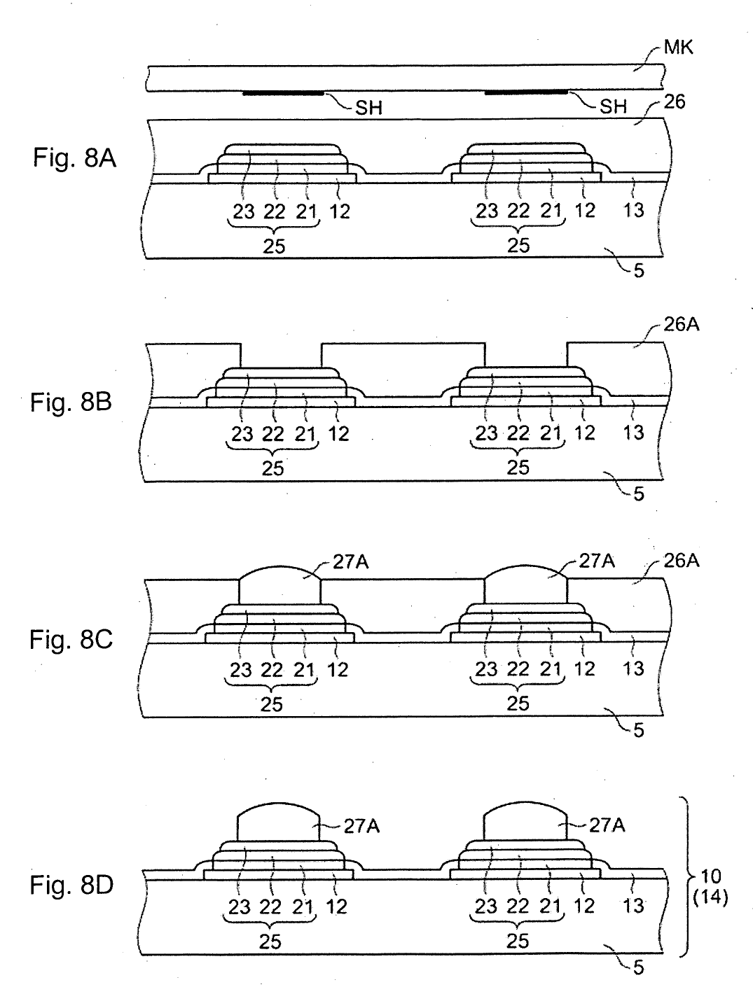

First, negative-type photoresist is applied using a spin coat method in order to obtain a resist layer 26 (FIG. 8A) to cover the insulating layer 13 and the UBM layer 25. More specifically, the photoresist is applied so that the entire surfaces of the insulating layer 13 and UBM layer 25 are covered by the resist layer 26. The thickness of the resist layer 26 obtained in the present embodiment is about 10 μm to 30 μm.

Next, the resist layer 26 is patterned so that the UBM layer 25 is exposed. More specifically, as shown in FIG. 8B, the resist layer 26 is irradiated with ultraviolet through a photo mask MK having a shield SH on a part corresponding to the UBM layer 25. Then, by developing with a given solution, a resist layer 26A having an aperture that exposes the UBM layer 25 is obtained.

Then, by printing, Su/Ag/Cu solder is coated on the UBM layer 25. As a result, as shown in FIG. 8C, a solder layer 27A is formed on the UBM layer 25. Thereafter, as shown in FIG. 8D, the resist layer 26A is denuded.

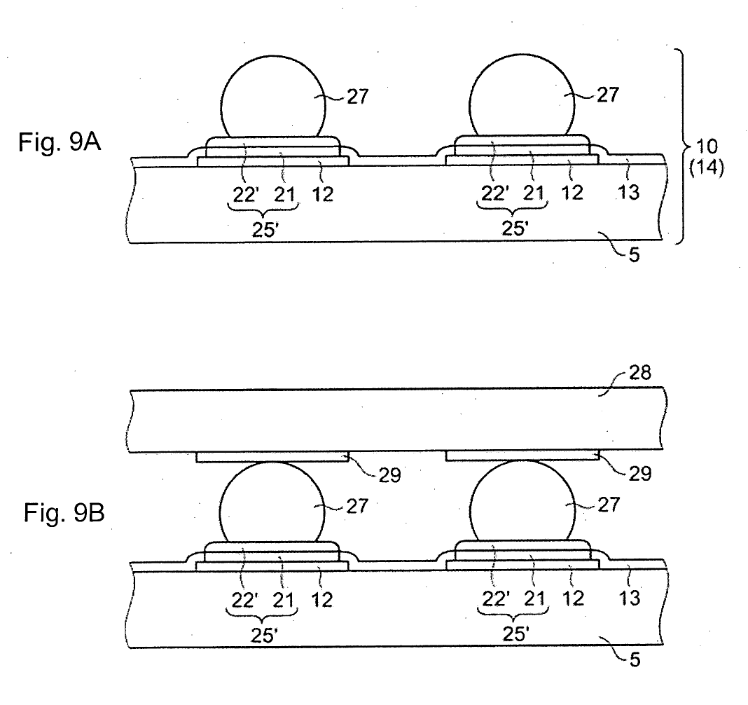

Then, as shown in FIG. 9A, a solder bump 27 is formed on the UBM layer 25 by reflowing the solder layer 27A. Additionally, as was mentioned, the semiconductor chip 10 with the solder bump 27 provided thereon is also expressed as “circuit element.”

Now, when reflowing the solder layer 27A, the Au atoms diffuse towards the solder bump 27 or towards the underlying metal layer; therefore, the third metal layer 23 practically disappears. Further, the second metal layer (Ni layer) 22 becomes a middle metal layer 22′ when reacted with Su and Cu contained in the solder layer 27A. Hereafter, the UBM layer 25 after reflowing the solder layer 27A will be expressed as “UBM layer 25′.” As shown in FIG. 9A, the UBM layer 25′ of the present embodiment includes the first metal layer 21 and the middle metal layer 22′.

(D4. Process for Mounting Semiconductor Chip)

After providing the solder bump 27 on the UBM layer 25′, a process for mounting the semiconductor chip 10 on the wiring substrate is conducted.

First, the back surface of the semiconductor wafer 14 is polished until the semiconductor wafer 14 obtains a given thickness. Then, by dicing, the plurality of semiconductor chips 10 are separated from the semiconductor wafer 14. Thereafter, each semiconductor chip 16 is mounted on each wiring substrate 28. More specifically, as shown in FIG. 9B, the semiconductor chip 10 is positioned against the wiring substrate 28 so that each solder bump 27 faces each land 29 on the wiring substrate 28. Note that the land 29 on the wiring substrate 28 is a part of copper wire.

Then, by melting the solder bump 27 again, the metal pad 12 of the semiconductor chip 10 and the land 29 of the wiring substrate 28 are physically and electrically connected through the UBM layer 25′ and the solder bump 27. As a result, the semiconductor chip 10 is mounted on the wiring substrate 28. Then, if necessary, the gap between the semiconductor chip 10 and the wiring substrate 28 is sealed by sealing resin such as epoxy resin. Additionally, in the present specification, the wiring substrate 28 with the semiconductor chips 10 mounted thereon is also expressed as “circuit substrate.”

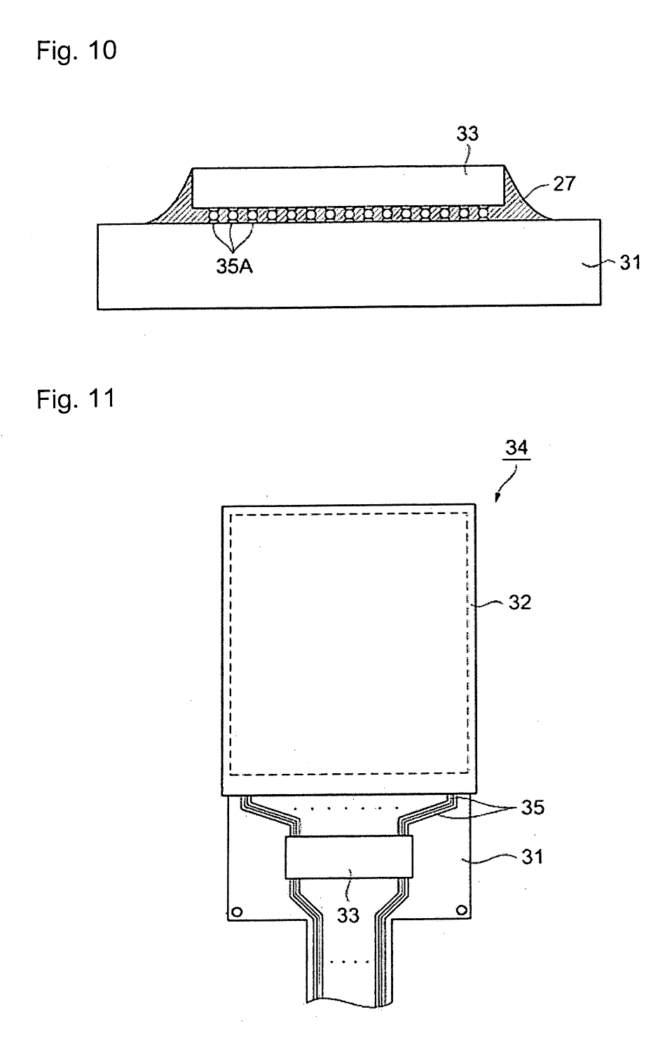

An example of the semiconductor chip 10 is a display controller 33 as shown in FIGS. 10 and 11. Here, the display controller 33 is a semiconductor element that drives a liquid-crystal panel 32. The display controller 33 is manufactured by the manufacturing method of the present embodiment.

More specifically, the UBM layer is provided on the metal pad of the display controller 33 by the manufacturing method of the present embodiment. Then, after providing the solder bump on the UBM layer, the display controller 33 is mounted on a flexible wiring substrate 31. More specifically, the solder bump is melted after positioning the display controller 33 to the flexible wiring substrate 31 in such a manner that the solder bumps come into contact with their corresponding lands 35A on the flexible wiring substrate 31.

Then, the flexible wiring substrate 31 having the display controller 33 mounted thereon is mounted on the liquid-crystal panel 32. More specifically, an electrode (not shown) on the liquid-crystal panel 32 and wire 35 on the flexible wiring substrate 31 are coupled using an anisotropic conductive adhesive agent. As a result, a liquid-crystal display device 34 can be obtained. Thus, the manufacturing method of the present embodiment can be applied to manufacture of the liquid-crystal controller device 34.

Further, the manufacturing method of the present embodiment can be applied to manufacture of various electro-optical devices in addition to the liquid-crystal display device 34. The “electro-optical device” mentioned here does not only mean a device that uses changes in optical features (namely, electro-optical effects) such as changes in birefringence, rotation, or scattering but also means any general device that projects, transmits, or reflects light depending on signal voltages applied.

More specifically, “electro-optical device” is a term that includes a liquid-crystal display device, electroluminescence display device, plasma display device, surface-conduction electron-emitter display (SED), field emission display (FED), and the like.

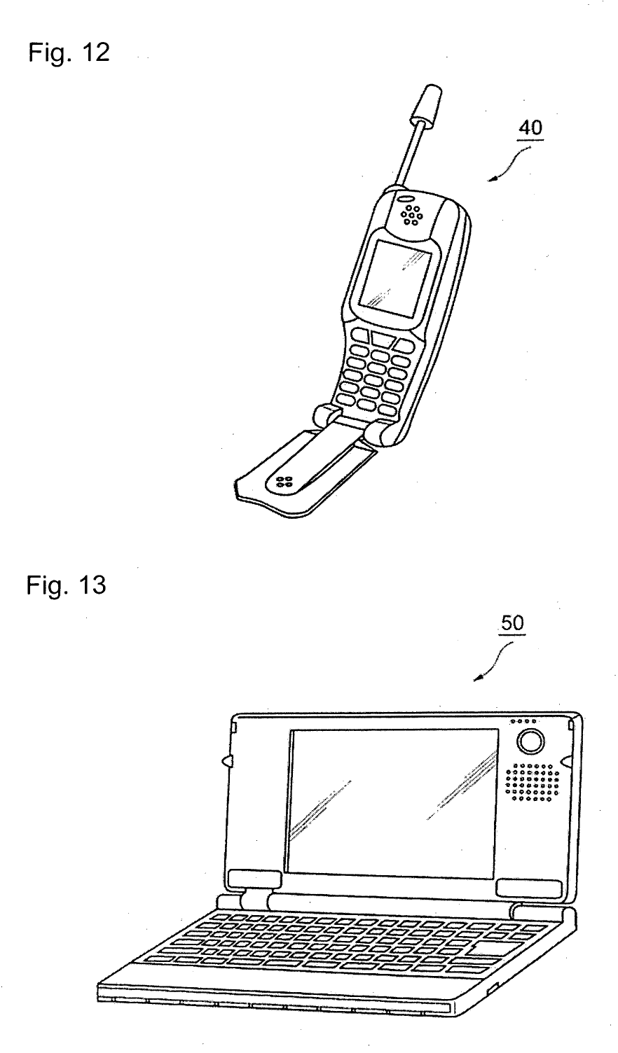

Further, the manufacturing method of the present embodiment can be applied to manufacture of various electronic devices. For example, it is applied to manufacture of a mobile phone 40 shown in FIG. 12 or of a personal computer 50 shown in FIG. 13.

### ALTERNATIVE EXAMPLE 1

According to the above-described embodiment, the UBM layer 25 before reflowing the solder layer 27A consists of three metal layers. However, if the underlying metal pad 12 and the solder bump 27 can be physically and electrically connected with each other, the UBM layer 25 may consist of one metal layer or four or more metal layers. More specifically, even when the UBM layer 25 consists only of the nickel layer, the solderability can be improved, and, therefore, the mounting technique using soldering can be applied to the circuit element having such UBM layer 25.

Further, the conductive material containing metals other than the metals described in the present embodiment may be used to form the UBM layer. Moreover, the liquid conductive material may contain an organic metal compound instead of fine metal particles. The organic metal compound mentioned here is such a compound that its metal is extracted when decomposed by heating.

### ALTERNATIVE EXAMPLE 2

According to the above-described embodiment, the three different dispensers 1A, 1B, and 1C dispense different conductive materials. In substitute for such a composition, one dispenser (e.g., the dispenser 1A) may dispense the above-described first conductive material 21A, second conductive material 22A, and third conductive material 23A. In this case, these first, second, and third conductive materials 21A, 22A, and 23A may be dispensed from separate nozzles 118 of the dispenser 1A or may be dispensed from one nozzle 118 of the dispenser 1A. When dispensing these four conductive materials 21A, 22A, and 23A, it only needs to add another process of washing the path from the tank 101A to the nozzle 118 when changing to another material.

It should be noted here that when dispensing these three conductive materials 21A, 22A, and 23A from one nozzle, the “first nozzle,” “second nozzle,” and “third nozzle” of the present invention correspond to one same nozzle 118.

### ALTERNATIVE EXAMPLE 3

According to the composition of the UBM layer 25 of the above-described embodiment, the first metal layer is a titanium (Ti) layer; the second metal layer is a nickel (Ni) layer; and the third metal layer is a gold (Au) layer. In addition to such a composition, the UBM layer may include the following three metal layers: a titanium (Ti) layer as the first metal layer; a mixed layer of titanium (Ti) and copper (Cu) as the second metal layer; and a copper (Cu) layer as the third metal layer. Further, in the UBM layer, the first metal layer may be a chromium (Cr) layer; the second metal layer may be a copper (Cu) layer; and the third metal layer may be a gold (Au) layer.

Even when the UBM layer has the composition as mentioned above, it can be manufactured by the manufacturing method of the above-described embodiment if the liquid conductive materials containing the corresponding fine metal particles are prepared.

### ALTERNATIVE EXAMPLE 4

According to the above-described embodiment, the first, second, and third conductive materials 21A, 22A, and 23A are eventually activated when heated with the oven. However, instead of heating, these conductive materials may be activated when irradiated with light having wavelength within regions of ultraviolet and visible light or irradiated with electromagnetic wave such as microwave. Also, instead of such activation, the conductive materials may simply be dried. This is because the conductive layer is produced by merely allowing the supplied conductive material to stand. However, it is faster to form the conductive layer when activated in some way than when simply left to dry. Therefore, it is preferable to activate the conductive material.

### ALTERNATIVE EXAMPLE 5

According to the above-described embodiment, the UBM layer is provided on the metal pad of the semiconductor element. However, the method for forming the UBM layer of the above-described embodiment may not only be applied for the metal pad of the semiconductor element but also be applied when providing the UBM layer on a lead terminal provided on a substrate of the semiconductor package. It should be noted that this semiconductor package corresponds to the “electronic element” of the present invention, and the lead element corresponds to the “conductive terminal” of the present invention. Further, an example of the semiconductor package is ball grid array (BGA) package. Furthermore, an example of the substrate of the semiconductor package is the above-described wiring substrate or the circuit substrate. If the method for forming the UBM layer of the above-described embodiment is used to manufacture the semiconductor package, it is possible to use metals other than copper as the material constituting the lead terminal that is provided on the substrate.

1. A method for manufacturing a circuit element utilizing a dispenser which is provided with a stage and a head having a nozzle that faces the stage, comprising:
(A) setting a semiconductor element on the stage so that a metal pad of the semiconductor element faces the head;
(B) changing positions of the head relative to the semiconductor element;
(C) dispensing a liquid conductive material from the nozzle so that the conductive material is supplied onto the metal pad when the nozzle reaches a position corresponding to the metal pad; and
(D) either activating or drying the supplied conductive material in order to obtain a UBM layer on the metal pad.

2. The method for manufacturing the circuit element according to claim 1, wherein:
the step C includes the step of dispensing a first liquid conductive material from a first nozzle so that the first conductive material is supplied onto the metal pad; and
the step D includes the step of either activating or drying the supplied first conductive material in order to obtain a first metal layer on the metal pad.

3. The method for manufacturing a circuit element according to claim 2, wherein:
the step C further includes the step of dispensing a second liquid conductive material from a second nozzle so that the second conductive material is supplied onto the first metal layer; and
the step D further includes the step of either activating or drying the supplied second conductive material in order to obtain a second metal layer on the first metal layer.

4. The method for manufacturing a circuit element according to claim 3, wherein:
the step C further includes the step of dispensing a third liquid conductive material from a third nozzle so that the third conductive material is supplied onto the second metal layer; and
the step D further includes the step of either activating or drying the supplied third conductive material in order to obtain a third metal layer on the second metal layer.

5. The method for manufacturing a circuit element according to claim 4, wherein:
the first conductive material contains a fine particle of titanium;
the second conductive material contains a fine particle of nickel; and
the third conductive material contains a fine particle of gold.

6. The method for manufacturing a circuit element according to claim 1, further comprising:
(E) forming a solder bump on the UBM layer; and
(F) reflowing the solder bump.

7. A circuit substrate manufactured by the method for manufacturing the circuit element according to claim 1.

8. An electronic device manufactured by the method for manufacturing the circuit element according to claim 1.

9. An electro-optical apparatus manufactured by the method for manufacturing the circuit element according to claim 1.

10. A method for manufacturing an electronic element utilizing a dispenser which is provided with a stage and a head having a nozzle that faces the stage, comprising:
(A) setting a substrate on the stage so that a conductive terminal of the substrate faces the head;
(B) changing positions of the head relative to the substrate;
(C) dispensing a liquid conductive material from the nozzle so that the conductive material is supplied onto the conductive terminal when the nozzle reaches a position corresponding to the conductive terminal; and
(D) either activating or drying the supplied conductive material in order to obtain a UBM layer on the conductive terminal.
